(19) United States
(12) Patent Application Publication
(10) Pub. No.: US 2025/0081546 A1
(43) Pub. Date: Mar. 6, 2025

(54) VERTICAL POWER COMPONENT

(71) Applicant: STMicroelectronics International N.V., Geneva (CH)

(72) Inventor: Frederic LANOIS, Tours (FR)

(73) Assignee: STMicroelectronics International N.V., Geneva (CH)

(21) Appl. No.: 18/810,349

(22) Filed: Aug. 20, 2024

(30) Foreign Application Priority Data
Aug. 28, 2023 (FR) 2309013

(51) Int. Cl. H01L 29/06; H01L 29/16; H01L 29/872

(52) U.S. Cl. CPC H10D 62/107; H10D 8/60; H10D 62/124; H10D 62/8325

(57) ABSTRACT

The present description relates to a vertical power component formed in and on a semiconductor substrate doped with a first conductivity type and coated, on the upper side thereof, with a semiconductor layer doped with the first conductivity type. The component includes: an active region (100A); and first and second groups of first concentric field limiting rings surrounding the active region. Each first ring includes a first semiconductor region doped with a second conductivity type, opposite to the first conductivity type, extending vertically into the thickness of the semiconductor layer from the upper side thereof; and a second field limiting ring laterally interposed between the first and second groups of first field limiting rings (GR). The second ring includes a second doped semiconductor region of the second conductivity type extending vertically into the thickness of the semiconductor layer from the upper face thereof. The second semiconductor region has a width at least three times larger than the width of the widest first semiconductor region.

### CROSS-REFERENCE TO RELATED APPLICATION(S)

This application claims the priority benefit of French patent application number FR2309013, filed on Aug. 28, 2023, entitled “Composant vertical de puissance” which is hereby incorporated by reference to the maximum extent allowable by law.

### BACKGROUND

### Technical Field

The present description relates in general to electronic devices. The present description relates more particularly to vertical power components.

### Description of the Related Art

Vertical power components have been proposed. Among such components, JBS (Junction-Barrier Schottky) diodes were more particularly proposed. JBS diodes have similar advantages to conventional Schottky diodes, including low ON-state voltage drop, low threshold voltage, and low switching losses. Furthermore, JBS diodes have a lower leakage current and an improved resistance in the event of current overload compared to conventional Schottky diodes.

However, existing vertical power components have various drawbacks. More particularly, electric arcs can appear inside such components when they are subjected to high reverse voltages. Electric arcs cause irreversible degradation in the vertical power components where arcs form, resulting in malfunctions which make the components at least partially inoperative.

### BRIEF SUMMARY

There is a desire to overcome all or some of the drawbacks of existing vertical power components. In particular, there is a desire to prevent the formation of electric arcs in existing vertical power components.

For such purpose, one embodiment provides a vertical power component formed in and on a semiconductor substrate doped with a first conductivity type and coated, on the upper side thereof, with a semiconductor layer doped with the first conductivity type, the component comprising:
an active region; and
first and second groups of first concentric field limiting rings surrounding the active region, each first ring comprising a first semiconductor region doped with a second conductivity type, opposite to the first conductivity type, extending vertically into the thickness of the semiconductor layer from the upper side thereof;
a second field limiting ring laterally interposed between the first and second groups of first field limiting rings, the second ring comprising a second doped semiconductor region of the second conductivity type extending vertically into the thickness of the semiconductor layer from the upper face thereof; and
a first insulating region (109) located on top and in mechanical contact with the entire upper face of the second doped semiconductor region (305P), wherein the second semiconductor region has a width at least three times larger than the width of the widest first semiconductor region.

According to one embodiment, the second ring reduces by at least half, for example by at least two thirds, an electric field present in the vicinity of an interface between the first insulating region, arranged on and in contact with the upper face of the semiconductor layer, and a second insulating region, located in a peripheral region of the vertical power component.

According to one embodiment, the second ring enables to reduce by at least half, for example by at least two thirds, an electric field present in the vicinity of an interface between the first insulating region, arranged on and in contact with the upper face of the semiconductor layer, and a molding resin of a package of the vertical power component.

According to one embodiment, the first and second groups comprise identical numbers of first rings.

According to one embodiment, the first and second field limiting rings are floating guard rings.

According to one embodiment, the component further comprises at least a third group of first rings, and at least one third field limiting ring interposed between the second group of first rings and said at least one third group of first rings.

According to one embodiment, the semiconductor layer has a doping level which is strictly lower than that of the semiconductor substrate.

According to one embodiment, the component comprises:
a first conduction electrode formed in the active region and including a conductive region located on the semiconductor layer; and
a second conduction electrode arranged on the side of a face of the semiconductor substrate opposite the semiconductor layer.

According to one embodiment, the semiconductor substrate is made of silicon or of silicon carbide.

According to one embodiment, the first conductivity type is N and the second conductivity type is P.

According to one embodiment, the component is a JBS diode

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1A and FIG. 1B are schematic and partial views, from above and in section, respectively, along the plane BB shown in FIG. 1A, illustrating an example of a vertical power component;

FIG. 2 is a schematic and partial top view of a peripheral region of the vertical power component shown in FIGS. 1A and 1B;

FIG. 3 is a detailed, schematic, and partial view of a peripheral region of a vertical power component according to one embodiment; and

FIG. 4 is a graph illustrating variations of the electric field and of the electrostatic potential in the peripheral region of the vertical power component shown in FIG. 3.

### DETAILED DESCRIPTION

Like features have been designated by like references in the various figures. In particular, the structural and/or functional features that are common among the various embodiments may have the same references and may dispose identical structural, dimensional, and material properties.

For the sake of clarity, the operations and elements that are useful for an understanding of the embodiments described herein have been illustrated and described in detail. In particular, the various applications implementing vertical power components were not described in detail, the embodiments described being compatible with all or most of the applications likely to take advantage of one or more vertical power components.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and, in some cases, within 5%.

In the following description, the qualifiers “insulating” and “conducting” mean, unless otherwise specified, electrically insulating and electrically conducting, respectively.

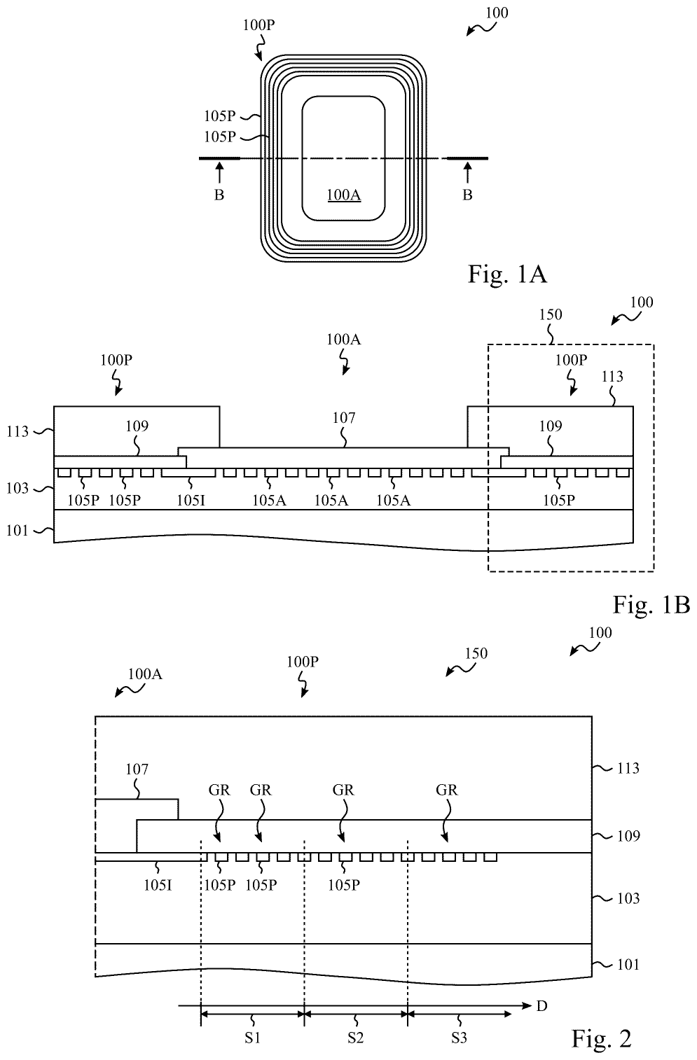

FIG. 1A is a schematic partial top view illustrating an example of a vertical power component 100. FIG. 1B is a section view, along the plane BB of FIG. 1A, of the vertical power component 100.

In the example illustrated, the vertical power component 100 is a JBS (Junction-Barrier Schottky) diode comprising an active region 100A, corresponding, e.g., to a region through which a power signal is likely to flow during operation of the component. In the present example, the active region 100A of the vertical power component 100 is flanked by a peripheral region 100P where the power signal is not intended to flow during the operation of the component. The active region 100A is, e.g., located substantially at the center of the vertical power component 100. The peripheral region 100P of the vertical power component 100 surrounds the active region 100A and has, e.g., an annular shape in top view. The peripheral region 100P is interposed laterally between the active region 100A and the edge of the vertical power component 100. FIG. 1A illustrates an example wherein the vertical power component 100 has, in top view, a generally rectangular shape. However, such example is not limiting, since the vertical power component 100 can, in a variant, have any general shape, e.g., a square shape, an oval shape, a circular shape, etc.

In the example shown, the vertical power component 100 is formed in and on a semiconductor substrate 101. The substrate 101 is, e.g., a wafer or a piece of a wafer made of a semiconductor material, e.g., silicon (Si) or silicon carbide (SIC). The semiconductor substrate 101 is doped with a first conductivity type, e.g., the N-type, and has, e.g., a doping level comprised between 1*10¹⁷ and 5*10²⁰ at./cm³ (N⁺ doping, in the case where the first conductivity type is the N-type). As an example, the semiconductor substrate 101 has a thickness greater than or equal to about 50 μm, the thickness of the semiconductor substrate 101 being, e.g., chosen so as to ensure the mechanical strength of the structure of the vertical power component 100.

The upper face, in the orientation shown in FIG. 1B, of the semiconductor substrate 101, is coated with a semiconductor layer 103. The semiconductor layer 103 is, e.g., made of the same material as the substrate 101, e.g., silicon or silicon carbide. As an example, the semiconductor layer 103 is an epitaxied layer, i.e., formed by epitaxial growth on the upper face of the semiconductor substrate 101. The semiconductor layer 103 is, e.g., doped with the first conductivity type (the N-type in the present example). The semiconductor layer 103 has, e.g., a doping level strictly lower than that of the semiconductor substrate 101, e.g., comprised between 1*10¹³ and 5*10¹⁷ at./cm³. The semiconductor layer 103 has, e.g., a doping level and a thickness chosen according to a voltage withstand to be achieved by the vertical power component 100.

In the example shown, the vertical power component 100 further comprises semiconductor regions 105A, 105I and 105P extending vertically in the thickness of the semiconductor layer 103 from its face opposite to the semiconductor substrate 101 (the upper face of the layer 103, in the orientation shown in FIG. 1B). The semiconductor regions 105A, 105I and 105P have a thickness strictly lower than the thickness of the semiconductor layer 103. In the example illustrated, the semiconductor regions 105A form part of the active region 100A, and the semiconductor regions 105I and 105P form part of the peripheral region 100P of the vertical power component 100, the region 105I being laterally interposed between the regions 105A and 105P. The semiconductor regions 105A, 105I and 105P are doped with a second conductivity type (P-type, in the present example) opposite to the first conductivity type. As an example, the semiconductor regions 105A, 105I and 105P have a maximum doping level comprised between 1*10¹⁷ and 5*10²⁰ at./cm³ (P+ doping, in the case where the second conductivity type is the P-type). The semiconductor regions 105A, 105I and 105P are, e.g., formed by an ion implantation step, on the side of the face of the semiconductor layer 103 opposite to the semiconductor substrate 101, followed by an annealing step. In FIG. 1A, the semiconductor regions 105A and 105P have not been shown in detail and certain semiconductor regions 105P (in the present case, three semiconductor regions 105P) have been shown so as not to overload the drawing. Moreover, the number of semiconductor regions 105A and 105P can be different from those shown in FIGS. 1A and 1B. As an example, the number of semiconductor regions 105P is comprised between five and three hundreds, for example comprised between ten and fifty, for example equal to around fifteen.

In the example illustrated, the semiconductor regions 105P and 105I have, in top view, concentric annular shapes, each semiconductor region 105P, 105I surrounding all semiconductor regions 105A. As an example, each semiconductor region 105P, 105I has a rectangular outline with rounded corners. The semiconductor regions 105A form, e.g., in top view, strips parallel to each other and extending laterally along a direction orthogonal to the plane BB. In a variant, the semiconductor regions 105A can form, in top view, a grid comprising first strips parallel to each other and orthogonal to the BB plane, and second strips parallel to each other and orthogonal to the first strips, hexagonal shapes, elliptical or round shapes, discontinuous strips, etc.

In the example shown, the vertical power component 100 further comprises a conductive region 107 arranged on and in contact with a portion of the upper face of the semiconductor layer 103 forming part of the active region 100A of the component 100, and with the upper faces of the semiconductor regions 105A and 105I. The conductive region 107 for example defines the active region 100A of the component 100. The conductive region 107 is, e.g., made of a metallic stack comprising, e.g., aluminum (Al). In such case, the region 107 forms, with the semiconductor layer 103, a Schottky contact (metal-semiconductor contact).

In the example illustrated, an insulating region 109 is arranged on and in contact with a part of the upper face of the semiconductor layer 103 which is a part of the peripheral region 100P of the vertical power component 100 with the upper faces of the semiconductor regions 105P and with a part of the semiconductor region 105I. The insulating region 109 has, e.g., in top view, an annular shape surrounding the active region 100A of the component 100. In the example shown, the conductive region 107 extends laterally on and in contact with a part of the upper face of the insulating region 109. The insulating region 109 acts, e.g., as a passivation layer for the vertical power component 100. As an example, the insulating region 109 is made of an oxide, e.g., silicon dioxide.

In the example shown, the vertical power component 100 further comprises another insulating region 113 located in the peripheral region 100P of the component 100 and arranged on and in contact with a part of the upper face of the conductive region 107 and with the upper face of the insulating region 109. The insulating region 113 has, e.g., in top view, an annular shape surrounding the active region 100A of the component 100. The insulating region 113 forms, e.g., a passivation layer for the vertical power component 100. As an example, the insulating region 113 is made of an organic material, e.g., a polymer, e.g., Polybutylene Oxide (PBO) or polyimide.

As a variant, the insulating region 113 can be omitted, the insulating region 109 being, in the case of a molded package assembly, in contact with a molding resin.

The vertical power component 100 further includes a conductive layer arranged on the side of a face of the semiconductor substrate 101 opposite the semiconductor layer 103 (the lower face of the semiconductor substrate 101, in the orientation shown in FIG. 1B). Such conductive layer is, e.g., part of another conduction electrode, e.g., a cathode, of the vertical power component 100. The conductive layer coating the lower face of the substrate 101 is, e.g., made of the same material as the conductive region 107, e.g., a metal (e.g., nickel) or a metal alloy.

Moreover, although not shown, the vertical power component 100 can be surrounded by a package, e.g., a package made of a polymer resin molded around the structure of the vertical power component 100.

FIG. 2 is a schematic and partial detail view of the peripheral region 100P of the vertical power component 100 shown in FIGS. 1A and 1B. FIG. 2 corresponds more precisely to a detailed section view of the region 150 delimited by a dotted frame in FIG. 1B.

In the example shown in FIG. 2, the semiconductor regions 105P have identical dimensions, within manufacturing dispersions, and are spaced apart substantially regularly. However, the example is not limiting, the semiconductor regions 105P being able to have, as a variant, different dimensions and/or spacings. In such case, the semiconductor regions 105P have, e.g., identical widths and a variable pitch, or variable widths and a constant pitch. The semiconductor regions 105P of the peripheral region 100P of the vertical power component 100 make it possible to spread the depletion zone of the main junction, formed at the interface between the semiconductor layer 103 and the conductive region 105I, over a distance suitable for ensuring the voltage withstand of the component 100.

In the example illustrated, the semiconductor regions 105P are correspondingly part of field limiting rings (GR), e.g., floating guard rings (FGR), each GR ring comprising a single semiconductor region 105P. As an example, the field limiting rings GR have spacings and widths dimensioned so that a substantially constant electric field can be obtained in the vicinity of the interface between the insulating regions 109 and 113 when the vertical power component 100 is subjected to a nominal voltage applied between the conduction electrodes thereof. As an example, the nominal voltage is, in absolute value, greater than or equal to 350 V, e.g., comprised between 600 V and 15 kV.

In the example shown, the field limiting rings GR of the vertical power component 100 have been divided into three sets (or groups) S1, S2 and S3 of rings GR each comprising substantially equal numbers of rings GR, hence of semiconductor regions 105P. In the example illustrated, the group S1 comprises the rings GR, the semiconductor regions 105P of which are the closest to the active region 100A of the vertical power component 100, the group S3 comprises the rings GR the semiconductor regions 105P of which are the furthest away from the active region 100A, and the group S2 comprises the rings GR the semiconductor regions 105P of which are interposed laterally between semiconductors regions of the group S1 and those of the group S3. In FIG. 2, an axis parallel to the upper face of the semiconductor substrate 101 and to the plane BB shown in FIG. 1A and oriented from the active region 100A towards the peripheral region 100P of the vertical power component 100, makes it possible to identify a distance (D) separating each GR, or each semiconductor region 105P, from the active region 100A.

A drawback of the vertical power component 100 is due to the fact that delamination or detachment phenomena can occur in particular between the package and the vertical power component 100, or between the insulating region 113 and the insulating region 109. In the case where the vertical power component 100 does not have the insulating region 113, delamination phenomena can take place between the insulating region 109 and the molding resin of the package. Delamination phenomena lead to the appearance of a gaseous layer, e.g., an air layer, wherein electric arcs can form, e.g., when the vertical power component is subjected to a high reverse voltage. The electric arcs cause irreversible damage in the vertical power component 100, thus leading to malfunctions making the vertical power component 100 at least partially inoperative.

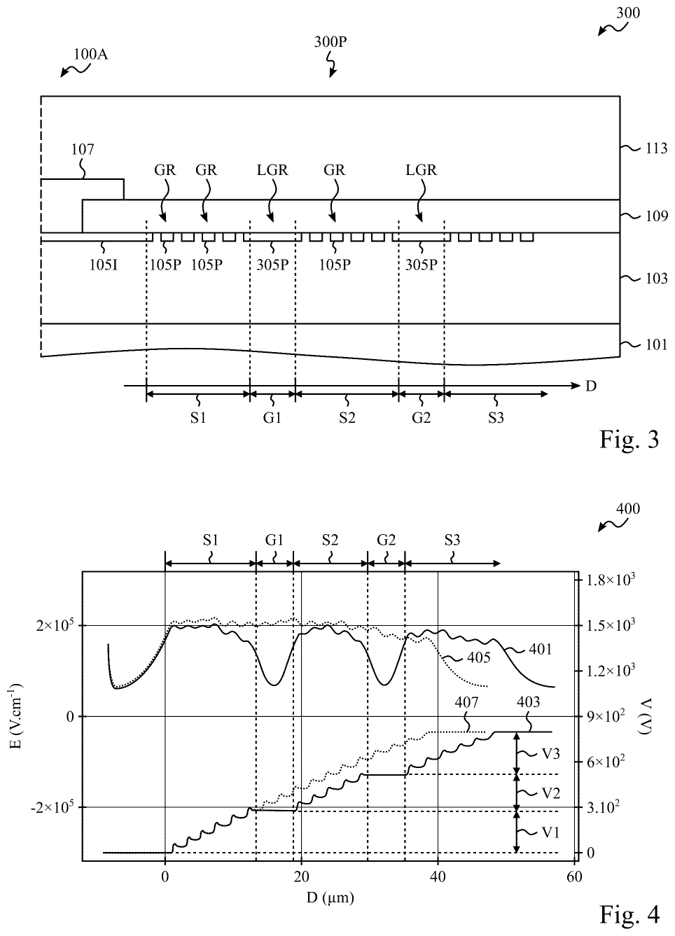

FIG. 3 is a schematic and partial detail view of a peripheral region of a vertical power component 300 according to one embodiment. In the example shown, the vertical power component 300 is a JBS diode. The vertical power component 300 shown in FIG. 3 comprises elements common to the vertical power component 100 shown in FIGS. 1A, 1B and 2. Such common elements will not be discussed in detail again hereinafter. The vertical power component 300 shown in FIG. 3 differs from the vertical power component 100 shown in FIGS. 1A, 1B and 2 in that the component 300 comprises a peripheral region 300P similar to the peripheral region 100P of the component 100 but comprising, in addition to the groups S1, S2 and S3 of field limiting rings GR comprising the semiconductor regions 105P, other field limiting rings (LGR), e.g., floating guard rings, each comprising a semiconductor region 305P.

The semiconductor regions 105P and 305P are for example concentric and each semiconductor region 305P is interposed laterally between two groups of semiconductor regions 105P. In other words, each field limiting ring LGR is interposed laterally between two groups (S1 and S2, or S2 and S3) of field limiting rings GR. In the example shown, the field limiting rings LGR form two gaps, or intervals, G1 and G2 respectively separating the group S1 from the group S2, and the group S2 from the group S3.

In the example illustrated in FIG. 3, each semiconductor region 305P extends vertically into the thickness of the semiconductor layer 103 from its face opposite to the semiconductor substrate 101 (the upper face of the layer 103, in the orientation shown in FIG. 3). The semiconductor regions 305P have a thickness strictly lower than the thickness of the semiconductor layer 103, e.g., a thickness substantially equal to the thickness of the semiconductor regions 105P. In the example illustrated, the semiconductor regions 305P form part of the peripheral region 300P of the vertical power component 300. The semiconductor regions 305P are doped with the second conductivity type (the P-type in the present example). As an example, the 305P semiconductor regions have a doping level comprised between 1*10¹⁷ and 5*10²⁰ at./cm³ (P⁺ doping, in the case where the second conductivity type is the P-type), e.g., a doping level substantially equal to that of the semiconductor regions 105P. The semiconductor regions 305P are for example formed by an ion implantation step, on the side of the face of the semiconductor layer 103 opposite the semiconductor substrate 101, followed by an annealing step. As an example, the semiconductor regions 105P and 305P are formed simultaneously.

According to one embodiment, each of the semiconductor regions 305P has a width strictly greater than the width of each of the semiconductor regions 105P. In other words, the field limiting rings LGR have a width strictly greater than the width of the field limiting rings GR. As an example, the width of each 305P semiconductor region is at least three times larger than the width of the widest 105P semiconductor region. In the example shown in FIG. 3, the semiconductor regions 305P have identical dimensions, within the manufacturing dispersions.

According to one embodiment, the insulating region 109 is located on top and in mechanical contact with the entire upper face of each of the semiconductor regions 305P. In particular, the vertical power component 300 lacks any electrically conductive elements in contact with the upper faces of the semiconductor regions 305P. In the example shown, the insulating region 109 is further located on top and in mechanical contact with the entire upper face of each of the semiconductor regions 105P. In particular, the vertical power component 300 lacks any electrically conductive elements in contact with the upper faces of the semiconductor regions 105P.

As an example, the number of field limiting rings LGR, or the number of groups of field limiting rings GR, is chosen according to a target voltage withstand of the vertical power component 300. Moreover, the number of field limiting rings GR in each group S1, S2, S3 is chosen, e.g., depending on a minimum voltage for forming an electric arc in the event of delamination, or detachment, in the vertical power component 300. The minimum voltage is, e.g., given by the Paschen law applied to the vertical power component 300. The geometry, number and distribution of the field limiting rings GR are defined so that the electric field near the interface between the insulating regions 109 and 113 is substantially constant over the groups S1, S2 and S3.

One advantage of the vertical power component 300 is that the presence of the rings LGR comprising the semiconductor regions 305P reduces the intensity of the electric field present in the vicinity of the interface between the insulating regions 109 and 113. It is thereby advantageously possible to prevent, or to limit, the risks of forming an electric arc in the event of delamination, or detachment, in the vertical power component 300.

FIG. 4 is a graph 400 illustrating, by curves 401 and 403, variations of electric field E, expressed in volts per centimeter (V.cm⁻¹), and of electrostatic potential (V), expressed in volts (V), respectively, in the peripheral region 300P of the vertical power component 300 shown in FIG. 3. As a comparison, the graph 400 further illustrates, by dashed curves 405 and 407, variations of the electric field E and of the electrostatic potential V, respectively, in the peripheral region 100P of the vertical power component 100. The graph 400 more precisely represents variations in the electric field E in the insulating region 109 of the vertical power component 100 or 300, e.g., in the vicinity of the interface with the insulating region 113, and in the electrostatic potential V in the semiconductor material, in the vicinity of the interface with the insulating region 109. Such variations are represented as a function of the distance D.

In the example shown, the curve 401 indicates that the electric field E is substantially constant, and equal to about 2*105 V.cm⁻¹, directly below each group S1, S2, S3 of rings GR, and that the electric field E decreases sharply, e.g., by a factor of two or three, in each gap G1, G2 located directly below an LGR ring. In other words, the field limiting rings LGR reduce the electric field E by half, for example by at least two thirds, compared to the constant field zones. As a comparison, the curve 405 indicates that the electric field E is substantially constant, and equal to about 2*105 V.cm⁻¹, along the distance axis D in the case of the vertical power component 100.

In the example illustrated in FIG. 4, the curve 403 indicates that the electrostatic potential V increases by a value V1 between the two ends of the group S1 of rings GR, by a value V2 between the two ends of the group S2 of rings GR and by a value V3 between the two ends of the group S3 of rings GR. Each of the values V1, V2 and V3 is, e.g., strictly lower than the minimum voltage above which an electric arc is likely to occur in the vertical power component 300 in the event of delamination or detachment. As an example, each value V1, V2, V3 is lower than 280 V, e.g., on the order of 250 V, the sum of the values V1, V2 and V3 being, e.g., equal to about 750 V. Moreover, in the example shown, the electrostatic potential V is substantially constant in the gaps G1 and G2, the curve 403 comprising plateaus corresponding to the position of the rings LGR. As a comparison, the curve 407 has no such plateaus.

As illustrated by the graph 400 in FIG. 4, an advantage of the vertical power component 300 lies in the fact that the presence of the field limiting rings LGR, interposed laterally between the groups S1, S2 and S3 of field limiting rings GR, creates weak electric field zones preventing the formation, in the event of delamination or detachment, of electric arcs with adverse effects for the operation of the component 300.

Various embodiments and variants have been described. Those skilled in the art will understand that certain features of these embodiments can be combined and other variants will readily occur to those skilled in the art. In particular, the embodiments described are not limited to the case wherein the vertical power component 300 is a JBS diode, but apply more generally to any type of vertical power component, e.g., a bipolar diode, a MOS (Metal-Oxide-Semiconductor) transistor, a thyristor, etc., comprising field limiting rings, e.g., to any type of vertical power component likely to be subjected to voltages greater than 350 V between the conducting electrodes thereof. The adaptation of the embodiments described to such components is within the scope of the person skilled in the art from the indications hereinabove.

Finally, the practical implementation of the embodiments and variants described herein is within the capabilities of those skilled in the art based on the functional description provided hereinabove. In particular, a person skilled in the art is able to adapt the number of groups of field limiting rings GR, the number of field limiting rings GR in each group of field limiting rings GR, and the lateral dimensions of each field limiting ring LGR depending on the application. Moreover, the embodiments are not limited to the examples of materials and dimensions described.

A vertical power component (300) may be formed in and on a semiconductor substrate (101) doped with a first conductivity type and coated, on the upper side thereof, with a semiconductor layer (103) doped with the first conductivity type. The component (300) may be summarized as including: an active region (100A); and first and second groups (S1, S2) of first concentric field limiting rings (GR) surrounding the active region (100A), each first ring (GR) comprising a first semiconductor region (105P) doped with a second conductivity type, opposite to the first conductivity type, extending vertically into the thickness of the semiconductor layer (103) from the upper side thereof; and—a second field limiting ring (LGR) laterally interposed between the first and second groups (S1, S2) of first field limiting rings (GR), the second ring (LGR) comprising a second doped semiconductor region (305P) of the second conductivity type extending vertically into the thickness of the semiconductor layer (103) from the upper face thereof; and a first insulating region (109) located on top and in mechanical contact with the entire upper face of the second doped semiconductor region (305P), wherein the second semiconductor region (305P) has a width at least three times larger than the width of the widest first semiconductor region (105P).

The second ring (LGR) reduces by at least half, preferentially by at least two thirds, an electric field (E) present in the vicinity of an interface between the first insulating region (109), arranged on and in contact with the upper face of the semiconductor layer (103), and a second insulating region (113), located in a peripheral region (100P) of the vertical power component (300).

The second ring (LGR) enables to reduce by at least half, preferably by at least two thirds, an electric field (E) present in the vicinity of an interface between the first insulating region (109), arranged on and in contact with the upper face of the semiconductor layer (103), and a molding resin of a package of the vertical power component (300).

The first and second groups (S1, S2) comprise identical numbers of first rings (GR).

The first and second field limiting rings (GR, LGR) are floating guard rings.

The component (300) further includes at least a third group (S3) of first rings (GR), and at least one third field limiting ring (LGR) interposed between the second group (S2) of first rings and said at least one third group (S3) of first rings.

The semiconductor layer (103) has a doping level which is strictly lower than that of the semiconductor substrate (101).

The component (300) may include: a first conduction electrode formed in the active region (100A) and including a conductive region (107) located on the semiconductor layer (103); and a second conduction electrode arranged on the side of a face of the semiconductor substrate (101) opposite the semiconductor layer.

The semiconductor substrate (101) is made of silicon or of silicon carbide.

The first conductivity type is N and the second conductivity type is P.

The component is a JBS diode.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A vertical power component comprising:
a semiconductor substrate doped with a first conductivity type;
a semiconductor layer doped with the first conductivity type on the semiconductor substrate;
an active region;
first and second groups of first field limiting rings surrounding the active region, each of the first field limiting rings including a first semiconductor region doped with a second conductivity type, opposite to the first conductivity type, extending into a thickness of the semiconductor layer;
a second field limiting ring laterally interposed between the first and second groups of the first field limiting rings, the second field limiting ring including a second semiconductor region doped with the second conductivity type, extending into the thickness of the semiconductor layer; and
a first insulating region on and in mechanical contact with an entire face of the second semiconductor region,
wherein the second semiconductor region has a width at least three times larger than a width of the widest first semiconductor region.

2. The vertical power component according to claim 1, further comprising:
a second insulating region located in a peripheral region of the vertical power component,
wherein the second field limiting ring is configured to reduce, by at least half, an electric field present in a vicinity of an interface between the first insulating region and the second insulating region.

3. The vertical power component according to claim 1, wherein the second field limiting ring enables to reduce, by at least half, an electric field present in a vicinity of an interface between the first insulating region and a molding resin of a package of the vertical power component.

4. The vertical power component according to claim 1, wherein the first and second groups include identical numbers of the first field limiting rings.

5. The vertical power component according to claim 1, wherein the first field limiting rings and the second field limiting ring are floating guard rings.

6. The vertical power component according to claim 1, further comprising:
at least one third group of the first field limiting rings; and
at least one third field limiting ring interposed between the second group of the first field limiting rings and the at least one third group of the first field limiting rings.

7. The vertical power component according to claim 1, wherein the semiconductor layer has a doping level that is lower than that of the semiconductor substrate.

8. The vertical power component according to claim 1, further comprising:
a first conduction electrode formed in the active region, and including a conductive region located on the semiconductor layer; and
a second conduction electrode arranged on a side of a face of the semiconductor substrate opposite the semiconductor layer.

9. The vertical power component according to claim 1, wherein the semiconductor substrate is made of silicon or of silicon carbide.

10. The vertical power component according to claim 1, wherein the first conductivity type is N and the second conductivity type is P.

11. The vertical power component according to claim 1, wherein the vertical power component is a Junction-Barrier Schottky (JBS) diode.

12. A device comprising:
a semiconductor substrate having a first conductivity type;
a semiconductor layer on the semiconductor substrate, the semiconductor layer having the first conductivity type; and
a power component on the semiconductor layer, the power component including an active region and a peripheral region surrounding the active region, the peripheral region including:
a first plurality of first semiconductor regions extending into the semiconductor layer, the first semiconductor regions having a second conductivity type;
a second semiconductor region extending into the semiconductor layer, the second semiconductor region having a width that is larger than each of the widths of the first semiconductor regions; and
a second plurality of the first semiconductor regions extending into the semiconductor layer, the first plurality of the first semiconductor regions being spaced from the second plurality of the first semiconductor regions by the second semiconductor region.

13. The device of claim 12, wherein the width of the second semiconductor region is at least three times larger than each of the widths of the first semiconductor regions.

14. The device of claim 12, further comprising:
a first insulating region is on the semiconductor layer, the first plurality of first semiconductor regions, the second semiconductor region, and the second plurality of the first semiconductor regions.

15. The device of claim 14 wherein the first insulating region physically contacts an entire face of the second semiconductor region.

16. The device of claim 14 wherein the active region includes a conductive region on the semiconductor layer, and the first insulating region is on the conductive region.

17. The device of claim 16, further comprising:
a second insulating region on the first insulating region and the conductive region.

18. The device of claim 12 wherein the semiconductor layer is an epitaxial layer.

19. A device comprising:
a semiconductor substrate having a first conductivity type;
a semiconductor layer on the semiconductor substrate, the semiconductor layer having the first conductivity type;
an active region in and on the semiconductor layer; and
a peripheral region surrounding the active region, the peripheral region including:
a first plurality of first semiconductor regions in the semiconductor layer;
a second plurality of the first semiconductor regions in the semiconductor layer, the first semiconductor regions having a second conductivity type;
a second semiconductor region in the semiconductor layer and between the first plurality of the first semiconductor regions and the second plurality of the first semiconductor regions, the second semiconductor region having a width that is larger than each of the widths of the first semiconductor regions; and
a first insulating region is on the semiconductor layer, the first plurality of first semiconductor regions, the second plurality of the first semiconductor regions, and the second semiconductor region.

20. The device of claim 19 wherein each of the first semiconductor regions and the second semiconductor region has a smaller thickness than the semiconductor layer.
